(19) United States
(12) Patent Application Publication
(10) Pub. No.: US 2009/0224301 A1
(43) Pub. Date: Sep. 10, 2009

(54) SEMICONDUCTOR MEMORY DEVICE AND METHOD OF MANUFACTURING THEREOF

(75) Inventors: Koji Yamakawa, Tokyo (JP); Soichi Yamazaki, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/399,856

(22) Filed: Mar. 6, 2009

(30) Foreign Application Priority Data
Mar. 6, 2008 (JP) 2008-056393

(51) Int. Cl. H01L 27/108; H01L 21/02

(52) U.S. Cl. 257/295; 438/3; 257/E27.084; 257/E21.009

(57) ABSTRACT

A semiconductor memory device comprises a field effect transistor including a source/drain region, an interlayer insulation film burying the field effect transistor, a ferroelectric capacitor including a lower electrode, a ferroelectric film and an upper electrode, the lower electrode with a concave-convex surface, and a plug electrically connecting between the source/drain region and the ferroelectric capacitor. A height and a size in an in-place direction of each convex portion in the concave-convex surface is 1 to 50 nm. The ferroelectric film includes a lower ferroelectric film with a predetermined height from the lower electrode and an upper ferroelectric film formed on the lower ferroelectric film as being formed from the same material as the lower ferroelectric film. The lower ferroelectric film includes a part of which at least one of composition, crystallizing orientation and size of a crystalline particle being different from a crystalline particle in the upper ferroelectric film.

### CROSS-REFERENCE TO RELATED APPLICATIONS

This application is based upon and claims the benefit of priority from the prior Japanese Patent Application No. 2008-56393, filed on Mar. 6, 2008; the entire contents of which are incorporated herein by reference.

### BACKGROUND OF THE INVENTION

1. Field of the Invention

The present invention relates to a semiconductor memory device and a method of manufacturing a semiconductor memory device, and in particular, relates to a semiconductor memory device provided with a capacitor that uses a ferroelectric film and a method of manufacturing such semiconductor memory device.

2. Description of the Related Art

In recent years, a development of a ferroelectric random access memory (hereinafter to be referred to as FeRAM) has been in progress from the perspective of achieving less power consumption, high integration, high-speed switching, high endurance, nonvolatility, and random accessibility. As a structure of the FeRAM, a structure which has one field effect transistor (hereinafter to be referred to as FET) and one ferroelectric capacitor of which a ferroelectric film is formed in between a pair of electrodes and in which a source region or a drain region of the FET and one of the electrodes of the ferroelectric capacitor are electrically connected is known.

The capacitor reliability, which owes to a leak characteristic of a ferroelectric capacitor, a C-V characteristic, an initial characteristic such as a polarization characteristic (i.e. an amount of polarization, a saturation characteristics, etc.), an imprint characteristic (i.e. a phenomenon in that polarization becomes easily directed toward one direction when the polarization is turned to and maintained at that direction), a fatigue characteristic (i.e. a degradation behavior in the amount of polarization caused by polarization inversion) and a retention characteristic (i.e. a degradation behavior in the amount of polarization), closely relates to materials of the electrodes and crystal structures of the materials. For this reason, in order to manufacture a ferroelectric capacitor with high capacitor reliability, selection of materials thereof will become important. As a ferroelectric film, a material having a crystal structure based on a perovskite structure and a residual polarization, such as Pb(Zrₓ,Ti₁₋ₓ)O₃ (i.e. PZT), Bi₄Ti₃O₁₂ (i.e. BIT) or SrBi₂Ta₂O₉ (i.e. SBT), or the like, can be used. As a material for a lower electrode, Ir, IrO₂, or Pt can be used. As a material for an upper electrode, a noble metal such as Pt, Ir or Ru, a noble metal oxide such as IrO₂, RuO₂, SrRuO₃ (i.e. SRO), LaNiO₃ (i.e. LNO) or CoO(La, Sr)₃ (i.e. LSCO), or a conductive compound oxide represented by a perovskite structure, or the like, can be used.

Accompanied by the recent miniaturization of a capacitor cell area, a COP structure disclosed in Japanese Patent Application Laid-Open No. 2003-258201, for instance, has become popular as a capacitor structure for the FeRAM. In this COP structure, a doped region of the FET formed on a substrate is directly connected to a lower electrode of the ferroelectric capacitor through a conductive plug, the lower electrode of the ferroelectric capacitor being formed over the doped region with an interlayer insulation film in between the doped region and the lower electrode. With respect to a method of manufacturing a ferroelectric capacitor that includes such structure, in forming the ferroelectric film on the lower electrode, a wafer will be heated at 600° C. or over in order to crystallize the ferroelectric film. Accordingly, there may be cases in that oxygen inside the ferroelectric film or inside a chamber in the deposition process will diffuse toward the conductive plug through the lower electrode. The oxygen diffused toward the conductive plug may oxidize the plug and cause poor contact. Therefore, in the conventional art, the lower electrode is formed on the conductive plug as having a laminated structure including a barrier film with an oxygen barrier ability and a metal film with high oxidation resistance.

Moreover, the miniaturization of the capacitor cell area can cause a problem in that process damages over the ferroelectric capacitor may become larger. This process damage can be defined as a phenomenon of fixed charges being formed in the ferroelectric film resulting in interfering polarization inversion of the ferroelectric substance. Such phenomenon in that fixed charges are formed in the ferroelectric film can be induced by hydrogen entering inside the ferroelectric film or trapping in around an interface between the ferroelectric film and the electrode during a CVD (chemical vapor deposition) process at a time of forming a mask for capacitor processing, a RIE (reactive ion etching) process for shaping the capacitor, a CVD process for forming the interlayer insulation film, and so forth, or by oxygen deficiency within the ferroelectric structure, a halogen-based gas intrusion into the ferroelectric film, and so forth. As a size of the ferroelectric capacitor becomes smaller, a ratio of a part that can suffer such process damages by a peripheral part in the ferroelectric capacitor becomes larger. As a result, deterioration in the amount of polarization of the ferroelectric capacitor can be caused. Furthermore, the miniaturization in the size of the ferroelectric capacitor can cause deterioration in the capacitor reliability, that is, deterioration in the fatigue characteristic, the retention characteristic, the imprint characteristic, etc. can be caused.

In this respect, conventionally, as disclosed in Japanese Patent Application Laid-Open No. 2003-174146, for instance, such process damages have been prevented by attempting to avoid hydrogen diffusion toward the capacitor portion by using an IrOₓ film, etc. for the upper electrode in order to let the ferroelectric capacitor have a hydrogen barrier characteristic, or by covering the peripheral part of the ferroelectric capacitor with a hydrogen barrier film such as Al₂O₃, SiN, or the like.

In the conventional art, however, although a structure for preventing possible influence of the process damages has been considered, the ferroelectric capacitor characteristic, which includes the tendency of polarization becoming easily inverted due to changes in external electric field in each domain within the ferroelectric film, has not be considered.

### BRIEF SUMMARY OF THE INVENTION

A semiconductor memory device according to embodiments of the present invention comprises: a field effect transistor including a source/drain region; an interlayer insulation film burying the field effect transistor; a ferroelectric capacitor including a lower electrode, a ferroelectric film and an upper electrode, the lower electrode with a concave-convex surface, a height and a size in an in-place direction of each convex portion in the concave-convex surface being 1 to 50 nm, the ferroelectric film including a lower ferroelectric film with a predetermined height from the lower electrode and an upper ferroelectric film formed on the lower ferroelectric film as being formed from the same material as the lower ferroelectric film, and the lower ferroelectric film including a part of which at least one of composition, crystallizing orientation and size of a crystalline particle being different from a crystalline particle in the upper ferroelectric film; and a plug electrically connecting between the source/drain region and the ferroelectric capacitor.

A method of manufacturing a semiconductor memory device according to embodiment of the present invention comprises: forming a field effect transistor including a source/drain region; forming an interlayer insulation film burying the field effect transistor; forming a contact hole in the interlayer insulation film, the contact hole exposing the source/drain region; forming a plug inside the contact hole, the plug being electrically connected to the source/drain region; forming a lower electrode on the interlayer insulation film, the lower electrode being electrically connected to the plug and having a concave-convex surface, a height and a size in an in-place direction of each convex portion in the concave-convex surface being 1 to 50 nm; forming a ferroelectric film by crystallization on the concave-convex surface of the lower electrode; and forming an upper electrode on the ferroelectric film.

### BRIEF DESCRIPTION OF THE DRAWINGS

FIG. 1 is a partial sectional view schematically showing one example of a structure of a semiconductor memory device according to a first embodiment of the present invention;

FIG. 2 is a partial sectional view schematically showing one example of a structure of a ferroelectric capacitor in the semiconductor memory device shown in FIG. 1;

FIG. 3A is a sectional view (Phase 1) schematically showing one example of processes in a method of manufacturing a semiconductor memory device according to the first embodiment;

FIG. 3B is a sectional view (Phase 2) schematically showing one example of processes in the method of manufacturing the semiconductor memory device according to the first embodiment;

FIG. 3C is a sectional view (Phase 3) schematically showing one example of processes in the method of manufacturing the semiconductor memory device according to the first embodiment;

FIG. 3D is a sectional view (Phase 4) schematically showing one example of processes in the method of manufacturing the semiconductor memory device according to the first embodiment;

FIG. 3E is a sectional view (Phase 5) schematically showing one example of processes in the method of manufacturing the semiconductor memory device according to the first embodiment;

FIG. 3F is a sectional view (Phase 6) schematically showing one example of processes in the method of manufacturing the semiconductor memory device according to the first embodiment;

FIG. 3G is a sectional view (Phase 7) schematically showing one example of processes in the method of manufacturing the semiconductor memory device according to the first embodiment;

FIG. 3H is a sectional view (Phase 8) schematically showing one example of processes in the method of manufacturing the semiconductor memory device according to the first embodiment;

FIG. 3I is a sectional view (Phase 9) schematically showing one example of processes in the method of manufacturing the semiconductor memory device according to the first embodiment;

FIG. 3J is a sectional view (Phase 10) schematically showing one example of processes in the method of manufacturing the semiconductor memory device according to the first embodiment;

FIG. 4 is a diagram for explaining a state of crystal particles formation in the vicinity of an interface between a lower electrode and a ferroelectric film shown in FIG. 1;

FIG. 5 is a diagram for explaining a state of crystal particles formation in the vicinity of the interface between the lower electrode and the ferroelectric film shown in FIG. 1;

FIG. 6A is a diagram (Phase 1) for explaining forming processes of the crystal particles in the vicinity of the interface between the lower electrode and the ferroelectric film shown in FIG. 1;

FIG. 6B is a diagram (Phase 2) for explaining forming processes of the crystal particles in the vicinity of the interface between the lower electrode and the ferroelectric film shown in FIG. 1;

FIG. 7 is a diagram schematically showing one example of domain inversion in the ferroelectric film shown in FIG. 1;

FIG. 8 is a diagram showing a relation between coverage of nano-structures in FIG. 1 with respect to a surface of the lower electrode and an amount of imprint;

FIG. 9 is a diagram showing a relation between coverage of the nano-structures in FIG. 1 with respect to the surface of the lower electrode and an amount of polarization;

FIG. 10A is a sectional view (Phase 1) schematically showing another example of processes in a method of manufacturing a semiconductor memory device according to the first embodiment;

FIG. 10B is a sectional view (Phase 2) schematically showing another example of processes in a method of manufacturing a semiconductor memory device according to the first embodiment;

FIG. 10C is a sectional view (Phase 3) schematically showing another example of processes in a method of manufacturing a semiconductor memory device according to the first embodiment;

FIG. 10D is a sectional view (Phase 4) schematically showing another example of processes in a method of manufacturing a semiconductor memory device according to the first embodiment;

FIG. 11A is a sectional view (Phase 1) schematically showing another example of processes in a method of manufacturing a semiconductor memory device according to the first embodiment;

FIG. 11B is a sectional view (Phase 2) schematically showing another example of processes in a method of manufacturing a semiconductor memory device according to the first embodiment;

FIG. 12 is a partial sectional view schematically showing one example of a structure of a semiconductor memory device according to a second embodiment of the present invention;

FIG. 13A is a sectional view (Phase 1) schematically showing one example of processes in a method of manufacturing a semiconductor memory device according to the second embodiment;

FIG. 13B is a sectional view (Phase 2) schematically showing one example of processes in a method of manufacturing a semiconductor memory device according to the second embodiment;

FIG. 13C is a sectional view (Phase 3) schematically showing one example of processes in a method of manufacturing a semiconductor memory device according to the second embodiment;

FIG. 14A is a sectional view (Phase 1) schematically showing one example of processes in a method of manufacturing a semiconductor memory device according to the second embodiment;

FIG. 14B is a sectional view (Phase 2) schematically showing one example of processes in a method of manufacturing a semiconductor memory device according to the second embodiment;

FIG. 14C is a sectional view (Phase 3) schematically showing one example of processes in a method of manufacturing a semiconductor memory device according to the second embodiment;

FIG. 15A is a partial sectional view schematically showing a modified example of a structure of the ferroelectric capacitor in the semiconductor memory device according to the first embodiment of the present invention;

FIG. 15B is a partial sectional view schematically showing another modified example of a structure of the ferroelectric capacitor in the semiconductor memory device according to the first embodiment of the present invention;

FIG. 16A is a partial sectional view schematically showing a modified example of a structure of the ferroelectric capacitor in the semiconductor memory device according to the second embodiment of the present invention;

FIG. 16B is a partial sectional view schematically showing another modified example of a structure of the ferroelectric capacitor in the semiconductor memory device according to the second embodiment of the present invention;

FIG. 17A is a partial sectional view schematically showing another modified example of a structure of the ferroelectric capacitor in the semiconductor memory device according to the second embodiment of the present invention;

FIG. 17B is a partial sectional view schematically showing another modified example of a structure of the ferroelectric capacitor in the semiconductor memory device according to the second embodiment of the present invention;

FIG. 18 is a partial sectional view schematically showing a modified example of the lower ferroelectric film according to the first or second embodiments of the present invention;

FIG. 19A is a partial sectional view schematically showing a modified example of a structure of the ferroelectric capacitor in the semiconductor memory device according to the first embodiment of the present invention;

FIG. 19B is a partial sectional view schematically showing a modified example of a structure of the ferroelectric capacitor in the semiconductor memory device according to the second embodiment of the present invention; and

FIG. 19C is a partial sectional view schematically showing another modified example of a structure of the ferroelectric capacitor in the semiconductor memory device according to the second embodiment of the present invention.

### DETAILED DESCRIPTION OF THE INVENTION

Exemplary embodiments of a semiconductor memory device and a method of manufacturing a semiconductor memory device according to the present invention will be explained below in detail with reference to the accompanying drawings. The present invention is not limited to the following embodiments. Furthermore, it is to be understood that sectional views of the semiconductor memory device used in describing the following embodiments are given for illustrative purposes, and therefore, relations among thicknesses and widths of layers, ratio of thicknesses of layers, etc. are different from what they actually are in practice. Moreover, the thicknesses of layers as will be shown in the following embodiments are examples, and therefore, the actual thicknesses of layers are not to be limited by such examples.

### First Embodiment

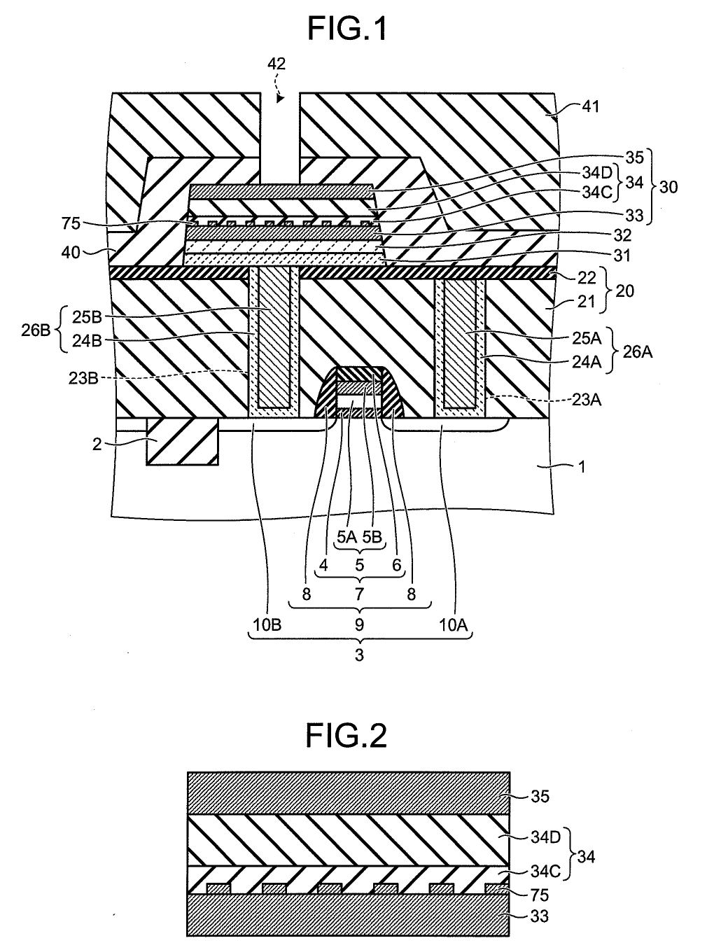

FIG. 1 is a partial sectional view schematically showing one example of a structure of a semiconductor memory device according to a first embodiment of the present invention. As shown in FIG. 1, in an upper surface of a semiconductor substrate 1, which is a p-type silicon substrate or the like, a field insulation film 2 formed with a silicon oxide film, etc. is formed. In an active region defined by the field insulation film 2, a MIS (metal-insulator-semiconductor) type electric field effect transistor (hereinafter to be referred to as MISFET) 3 with a structure of metal-insulator-semiconductor junction is formed. The MISFET 3 includes a gate structure 9, and source/drain regions 10A and 10B. The gate structure 9 is composed as including; a gate stack 7 in which a gate insulator 4, a gate electrode 5 which is to be a part of a word line, and a gate cap 6 are being laminated; and gate sidewall spacers 8 which are formed on both side surfaces of the gate stack 7 in a gate length direction of the gate stack 7. The source/drain regions 10A and 10B make up a pair while they have a channel region underneath the gate structure 9 sandwiched in between. For example, a silicon oxide film can be used for the gate insulator 4, a polycide structure in which an n-type polysilicon film 5A and a WSi₂ film 5B are laminated can be used for the gate electrode 5, and silicon nitride films can be used for the gate cap film 6 and the gate sidewall spacers 8.

On the semiconductor substrate 1 with the MISFET 3 formed in the above-described manner, a first interlayer insulation film 20 having a planarized surface is formed to a thickness of 1050 to 1350 nm. Here, the first interlayer insulation film 20 has a structure where a silicon oxide film 21 and a laminated film 22, with a three-layer structure of a silicon oxide film, a silicon nitride film and a silicon oxide film, are laminated in sequence. Contact holes 23A and 23B which penetrate in a thickness direction of the first interlayer insulation film 20 are formed at positions corresponding to the sauce/drain regions 10A and 10B of the first interlayer insulation film 20. Inside the contact holes 23A and 23B, conductive diffusion stopper films 24A and 24B which cover internal surfaces of the contact holes 23A and 23B, and plugs 25A and 25B with which the contact holes 23A and 23B are filled are formed at least. The diffusion stopper films 24A and 24B are films for preventing metals that constitute contact plugs 26A and 26B from diffusing toward the first interlayer insulation film 20. A thickness of the diffusion stopper films 24A and 24B can be 5 to 10 nm, for example. In the present embodiment, the contact plug 26B is formed on one source/drain region 10B as penetrating through the whole first interlayer insulation film 20, whereas the contact plug 26A is formed on the other source/drain region 10A as penetrating only the silicon oxide film 21 at the lowest layer in the first interlayer insulation film 20. However, the present invention is not limited to such structure. As the diffusion stopper films 24A and 24B, TiN films, etc. can be used, for example. As the plugs 25A and 25B, W, doped polysilicon, or the like can be used, for example.

On a certain region over the four-layer structured first interlayer insulation film 20 which is a peripheral region including an upper surface of the contact plug 26B that penetrates through the whole first interlayer insulation film 20, an adhesive film 31 and a capacitor barrier film 32 are formed in sequence. Moreover, on the capacitor barrier film 32, a ferroelectric capacitor 30 includes a lower electrode 33 formed on the capacitor barrier film 32, and a ferroelectric film 34 and an upper electrode 35 formed on the lower electrode 33 in sequence.

The adhesive film 31 is a film for enhancing adhesiveness between the first interlayer insulation film 20 and the capacitor barrier film 32, and can be formed with a conductive film such as TiAl, or the like, to a thickness of about 5 nm. The capacitor barrier film 32 is formed in between the ferroelectric capacitor 30 and the contact plug 26B. The capacitor barrier film 32 serves to prevent oxygen from diffusing from the ferroelectric film 34 toward the contact plug 26B, and has a hydrogen barrier ability. This capacitor barrier film 32 is formed with a conductive film to a thickness of about 30 nm, for example. As a material for the capacitor barrier film 32, TiAlN, TaSiN, TiN, TiSiN, or the like can be used, for example.

The lower electrode 33 (electrode layer) is formed with a conductive film with high oxidation resistance to a thickness of about 100 nm. For this lower electrode 33, a conductive film formed with such as Ir, Pt, IrOₓ, or the like can be used, or a laminated film constructed from such conductive films can be used. FIG. 2 schematically shows one example of a structure of a ferroelectric capacitor portion in the semiconductor memory device shown in FIG. 1. As shown in FIG. 1 and FIG. 2, nano-structures 75 are formed on a surface of the lower electrode 33. Each nano-structure 75 is 1 to 50 nm high from the surface (upper surface) of the lower electrode, and a size thereof in an in-plane direction with respect to the surface of the lower electrode 33 is 1 to 50 nm. Due to such nano-structures 75, the lower electrode 33 has a concave-convex surface while each convex portion has a height and a size in the in-plane direction both equal to or greater than 1 nm but not exceeding 50 nm. Such nano-structures 75 are formed by arranging conductive oxides with perovskite structures (e.g. LNO (LaNiO₃) or SRO (SrRuO₃)) into islands arrangement.

On the lower electrode 33 including such nano-structures 75 at the upper surface thereof, a ferroelectric film 34 formed with a ferroelectric material having a crystal structure based on a perovskite structure such as PZT, BIT, SBT, or the like is formed. As the ferroelectric film 34, a thin film with a thickness of about 100 nm can be used, for example. The ferroelectric film 34 is configured as including a lower ferroelectric film 34C which has a predetermined thickness from the upper surface of the lower electrode 33, and an upper ferroelectric film 34D which is formed on the lower ferroelectric film 34C and formed with a ferroelectric material of the same material as that of the lower ferroelectric film 34C.

Here, in a case of forming the ferroelectric film 34 by crystallizing the material at high temperature using a MOCVD method or a sputtering method, a growth behavior of the ferroelectric film 34 will become different depending on a base shape (i.e. a shape of the upper surface of the lower electrode 33). That is, in a case of forming a ferroelectric film on the lower electrode 33 having the nano-structures 75 each of which with the height and the size in the in-plane direction both equal to or greater than 1 nm but not exceeding 50 nm, two kinds of crystal particles, i.e. a kind of crystal particles to be growing on surfaces of the nano-structures 75 and a kind of crystal particles to be growing on the surface of the lower electrode 33, will be generated. In other words, compositions, crystallizing orientations, and particle sizes of the crystal particles of the ferroelectric film to be developed on the lower electrode 33 will differ depending on whether the ferroelectric film is developed on the nano-structures 75 or the lower electrode 33 as being the base shapes. Therefore, the lower ferroelectric film 34C formed on the lower electrode 33 having the nano-structures 75 is to include portions with crystal particles of which at least one of composition, crystallizing orientation and particle size is different from crystal particles in the upper ferroelectric film 34D formed on the lower ferroelectric film 34C. Specifically, the lower ferroelectric film 34C has a structure finer than the upper ferroelectric film 34D since the lower ferroelectric film 34C has different finer structure due to the nano-structures 75 formed on the surface of the lower electrode 33.

It is preferable that a height of the nano-structures 75 is 1 to 50 nm. If the height of the nano-structures 75 is less than 1 nm, steps between the nano-structures 75 and the upper surface of the lower electrode 33 will become too small, and it will be difficult to have crystal particles with different compositions, crystallizing orientations and particle sizes to be formed in the lower ferroelectric film 34C. Moreover, if the height of the nano-structures 75 is over 50 nm, the steps between the nano-structures 75 and the upper surface of the lower electrode 33 will become too large, and it will be difficult of have crystal particles with different compositions, crystallizing orientations and particle sizes to be formed in the lower ferroelectric film 34C. In addition, if the height of the nano-structure 75 is 1 to 20 nm, it will be possible to have crystal particles with different compositions, crystallizing orientations and particle sizes formed in the lower ferroelectric film 34C with better controllability.

It is preferable that a size of each of the nano-structures 75 in the in-plane direction is 1 to 50 nm. If the size of the nano-structure 75 in a direction parallel with the electrode surface is less than 1 nm, or over 50 nm, it will be difficult of have crystal particles with different compositions, crystallizing orientations and particle sizes to be formed in the lower ferroelectric film 34C with good controllability. In addition, if the size of the nano-structure 75 in a direction parallel with the electrode surface is 1 to 30 nm, it will be possible to have crystal particles with different compositions, crystallizing orientations and particle sizes formed in the lower ferroelectric film 34C with better controllability.

As the upper electrode 35, a film with a proper thickness that does not cause the ferroelectric capacitor characteristic deteriorate or cause reliability degradation with the ferroelectric capacitor 30 is to be used. In this respect, for example, a film with a thickness of 100 nm or less can be used as the upper electrode 35. With respect to such film to be used as the upper electrode 35, the possible options are: a film formed with a noble metal such as Ir, Ru, Pt, or the like; a film formed with a noble metal oxide such as IrOₓ, RuOₓ, or the like; a laminated film formed with the above-mentioned noble metal film and noble metal oxide film; and a laminated film formed with the above-mentioned noble metal film, and/or noble metal oxide film, and a film formed with a conductive oxide such as SRO, LNO, LSCO, or the like. The above-mentioned conductive oxide film, when arranged at the interface in between a ferroelectric film such as PZT and the electrode, can exhibit its function of compensating for oxygen deficiency. Due to such function, an advantageous effect in that deterioration with respect to the fatigue characteristic of the ferroelectric capacitor 30 can be prevented will become available.

A hydrogen barrier film 4 is formed in a way covering the surface and the side surfaces of the ferroelectric capacitor 30 on the first interlayer insulation film 20. The hydrogen barrier film 40 is formed with Al₂O₃, SiN, or the like to a thickness of about 50 nm. On the hydrogen barrier film 40, a second interlayer insulation film 41 is formed. The second interlayer insulation film 41 is formed with a silicon oxide, or the like, to a thickness of 200 to 500 nm. On the second interlayer insulation film 41, upper layer wirings, which is not shown, are formed. This upper layer wirings are electrically connected with wirings in the lower layer, the upper electrode 35, etc. through a via hole 42.

In this way, according to the present embodiment, due to having the ferroelectric film 34 formed on the lower electrode 33 that has the nano-structures 75, the lower ferroelectric film 34C will be formed in the ferroelectric film 34 around the interface with the lower electrode 33 as being composed of crystal particles which are smaller in particle size than those produced under normal film forming conditions, crystal particles which are oriented in a certain direction, or crystal particles with different compositions. Thereby, in the present embodiment, it is possible to reduce the stress on the electrode interface and cause polarization inversion easily. As a result, the ferroelectric capacitor characteristic can be improved.

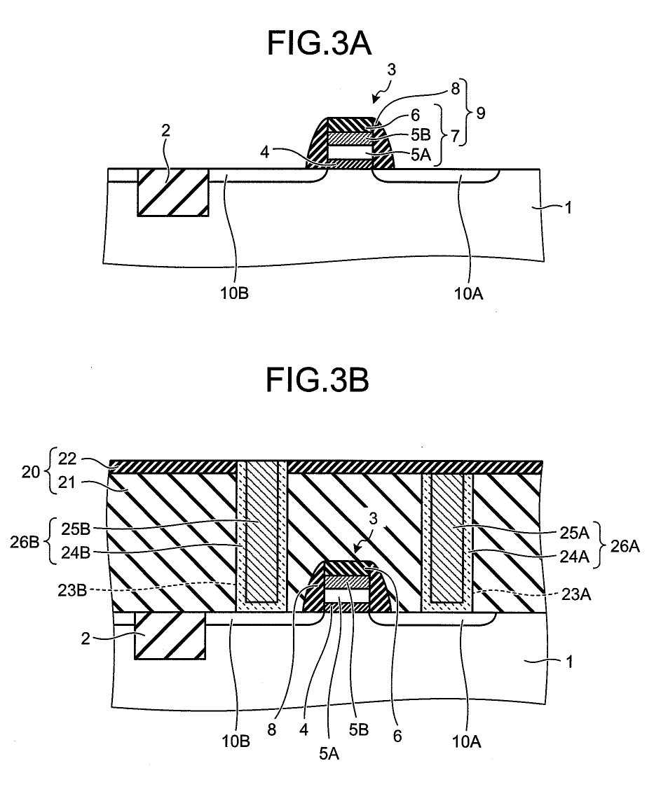

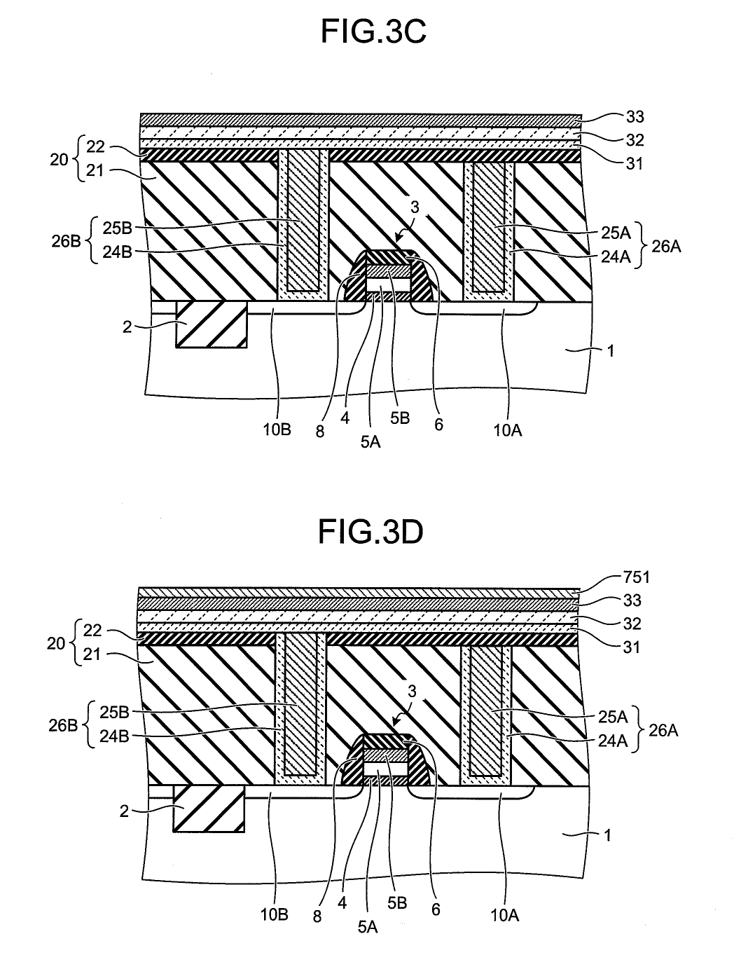

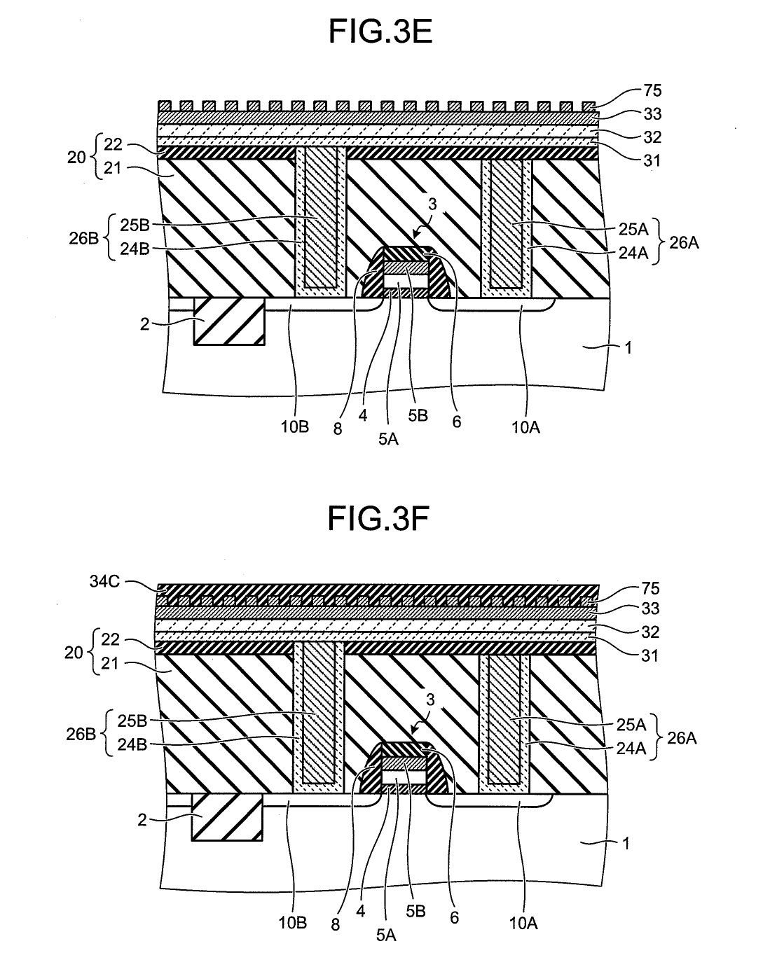

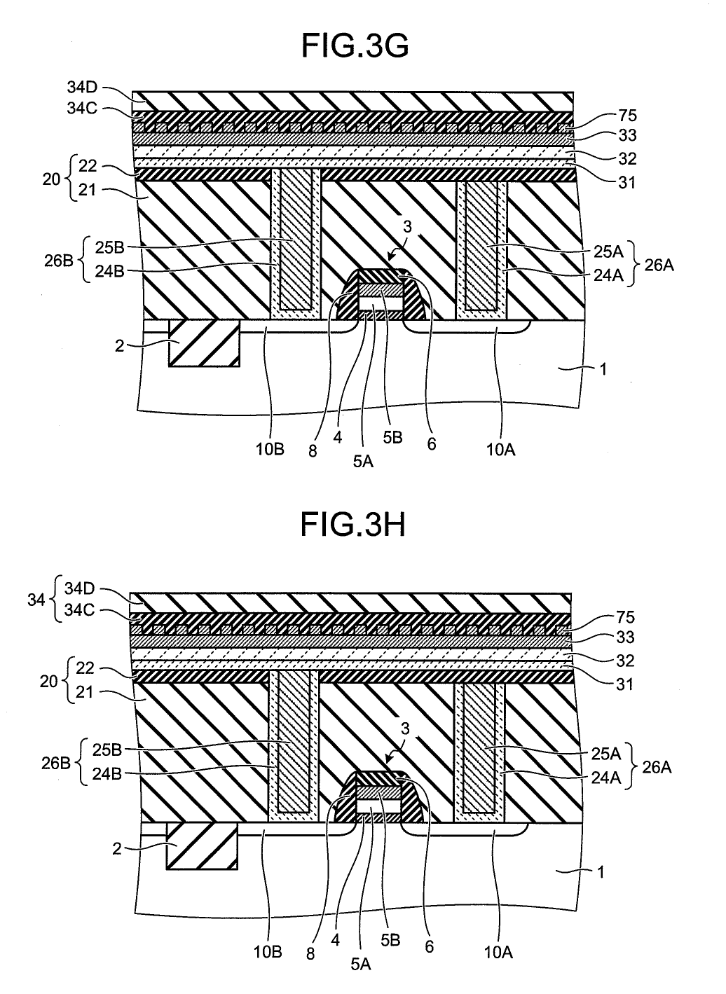

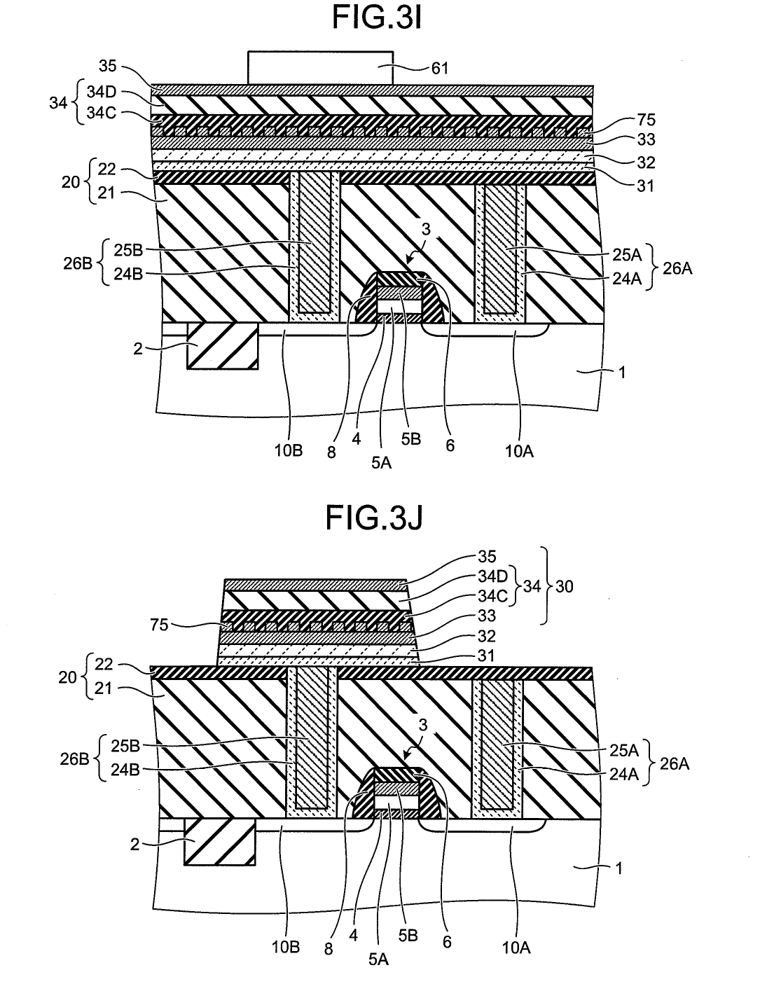

Now, a method of manufacturing the semiconductor memory device shown in FIG. 1 will be described. FIG. 3A to FIG. 3J are sectional views schematically showing one example of processes in the method of manufacturing the semiconductor memory device according to the first embodiment of the present invention. Here, the description will be about a case in which PZT is used as the ferroelectric film 34.

First, using a STI (shallow trench isolation) method or the like, the field insulation film 2 with a predetermined pattern is formed on the semiconductor substrate 1 which could be a p-type silicon substrate or the like. Then, the MISFET 3 is formed at a region of the semiconductor substrate 1 surrounded by the field insulation film 2. Thereby, a sectional structure shown in FIG. 3A can be obtained.

In forming the MISFET 3, for instance, a laminated film is formed by sequentially forming the gate insulator 4, the n-type polysilicon film 5A, the WSiₓ film 5B and the gate cap film 6 on the semiconductor substrate 1, while the gate insulator 4 may be a silicon oxide film or the like, the n-type polysilicon film 5A may be doped with arsenic, and the gate cap film 6 may be a nitride silicon film or the like. Then, this laminated film is processed into a predetermined shape by normal lithographic and RIE methods. Thereby, the gate stack 7 composed of the gate insulator 4, the gate electrode 5, and the gate cap 6 is formed. Then, ions are implanted into the semiconductor substrate 1 while the gate stack 7 is serving as a mask, and a heat treatment is performed on the injected ions. Thereby, predetermined conductive-type source/drain regions 10A and 10B are formed on the surface of the semiconductor substrate 1 on both sides of the gate stack 7 in a line width direction of the gate stack 7. In other words, the source/drain regions 10A and 10B are formed in the regions of the semiconductor substrate 1 between which of under portion of the gate stack 7 is sandwiched in a gate length direction of the MISFET 3. Then, an insulation film such as a silicon nitride film is formed on the semiconductor substrate 1, after which the insulation film deposited on the surface of the semiconductor substrate 1 is etched back by anisotropic etching using a RIE method. Thereby, the insulation film is partially removed such that the insulation films remain on both side surfaces of the gate stack 7 in the line width direction. The insulation films remaining on the both side surfaces of the gate stack 7 in the line width direction are to be the gate sidewall spacers 8. Through such processes, the gate structure 9 composed of the gate insulator 4, the gate electrode 5, the gate cap film 6, and the gate sidewall spacers 8 is formed on the semiconductor substrate 1. Thus, the MISFET 3 is formed at a predetermined region surrounded by the field insulation film 2.

Next, using a CVD method, the silicon oxide film 21 is formed on the semiconductor substrate 1, where the MISFET 3 has been formed, to a thickness of 600 to 700 nm in a way covering the MISFET 3. Then, an upper surface of the silicon oxide film 21 is planarized by a CMP (chemical mechanical polishing) method. After that, the contact hole 23A which is to contact with one of the source/drain regions of the MISFET 3, i.e. the source/drain region 10A, is formed in the silicon oxide film 21. In other words, the contact hole 23A is formed in the silicon oxide film 21 in a way exposing one source/drain region 10A of the MISFET 3. Then, thin Ti film with a thickness of 5 to 10 nm is formed on the inner side and bottom surfaces of the contact hole 23A using a sputtering method, a CVD method, or the like. The thin Ti film is to be processed into the diffusion stopper film 24A. Then, by carrying out a heat treatment in a forming gas, a TiN film which is to be the diffusion stopper film 24A is formed in a way covering the inner side and bottom surfaces of the contact hole 23A. Then, a W film is formed on the silicon oxide film 21 including inside the contact hole 23A by a CVD method, after which the W film is removed from regions except for the inside of the contact hole 23A by a CMP method. Then, by selectively filling up inside the contact hole 23A with W, the plug 25A is formed. Through such processes, the contact plug 26A composed of the diffusion stopper film 24A and the plug 25A is formed inside the contact hole 23A.

Next, using a CVD method, the laminated film 22 is formed on the entire surface of the silicon oxide film 21 where the contact plug 26A has been formed. The laminated film 22 is formed with a silicon oxide film with a thickness of 200 to 300 nm, a silicon nitride film with a thickness of about 50 nm, and a silicon oxide film with a thickness of 200 to 300 nm. Then, an upper surface of the laminated film 22 is planarized by a CMP method. The first interlayer insulation film 20 is formed with the above-described silicon oxide film 21 and the laminated film 22 with a laminated structure of silicon oxide film-silicon nitride film-silicon oxide film. Then, the contact hole 23B which is to contact with the other one of the source/drain regions of the MISFET 3, i.e. the source/drain region 10B, is formed in the first interlayer insulation film 20. In other words, the contact hole 23B is formed in the first interlayer insulation film 20 in a way exposing the other source/drain region 10B of the MISFET 3. Then, using the same methods as in the case of the contact plug 26A, a TiN film which is to be the diffusion stopper film 24B is formed inside the contact hole 23B, after which the contact hole 23B is filled up inside with W which is to be the plug 25B. Thereby, the contact plug 26B to be connected with the ferroelectric capacitor 30, which will be formed in the subsequent processes, is formed, as shown in FIG. 3B.

Next, the adhesive film 31 and the capacitor barrier film 32 are formed in sequence on the first interlayer insulation film 20 where the contact plug 26B has been formed. The adhesive film 31 is about 5 nm thick, and is composed of TiAl, etc. The capacitor barrier film 32 is about 30 nm thick, and is composed of TiAlN, etc. The TiAl film can be formed by a sputtering method using a TiAl metal target, for example. The TiAlN film can be formed by a reactive sputtering method using a TiAl metal target in a gas atmosphere to which N₂ is added. In this case, it is possible to improve the crystallinity of the deposited TiAlN film by high-temperature film formation or heat treatment. Thereby, it will be possible to reduce the stress inside the TiAlN film. Then, the lower electrode 33 is formed on the capacitor barrier film 32 by a sputtering method. The lower electrode 33 is about 100 nm thick, and is composed of Ir, etc. Thus, a sectional structure shown in FIG. 3C can be obtained. In the case of using Ir as the material, it is preferable that the film is formed by sputtering at a high temperature of 300° C. or over in order to prevent hillock formation.

Next, as shown in FIG. 3D, a nano-structure base film 751, such as a LNO film, to be processed into the nano-structures 75 is formed on the lower electrode 33. That is, the nano-structure base film 751 is a film to be processed into the nano-structures 75, and is formed with the same material as the nano-structures 75. This nano-structure base film 751, for instance, is an amorphous film with a thickness of 100 Å or less, and can be formed by various film formation methods such as sputtering method, ALD method, CVD method, vapor deposition method, etc. Then, the amorphous ferroelectric film is crystallized by a heat treatment such as RTO (rapid thermal oxidation) at a temperature of 600° C. Thereby, the nano-structures 75 in islands arrangement can be formed on the surface of the lower electrode 33, as shown in FIG. 3E.

Next, using a MOCVD (metal organic chemical vapor deposition), the lower ferroelectric film 34C that composes the ferroelectric film 34 is formed in-situ on the lower electrode 33 which has the nano-structures 75 (cf. FIG. 3F), after which the upper ferroelectric film 34D that composes the ferroelectric film 34 is formed (cf. FIG. 3G) on the lower ferroelectric film 34C. The ferroelectric film 34 constituted with the lower ferroelectric film 34C and the upper ferroelectric film 34D is a PZT film with a thickness of 95 to 100 nm, for example. A film formed by the MOCVD method will have little defect inside the film and little defect with the electrode interface. Thereby, the film has good polarization characteristic, and high reliability with respect to fatigue characteristic, imprint characteristic and retention characteristic. Therefore, it is preferable that the ferroelectric film 34 is formed using the MOCVD method. Furthermore, the MOCVD method is a preferable method to be used for forming the ferroelectric film (PZT film) due to some of the advantages the method can provide, which are; the MOCVD method proves good step coverage with respect to the electrode structure; the MOCVD method has excellent composition controllability; the MOCVD method can produce a uniform and high quality film with a large area; the MOCVD method exhibits high film formation speed; the MOCVD method can make the ferroelectric film 34 (PZT film) thinner (i.e. low voltage switching is possible with the MOCVD method); and so forth. Moreover, with the MOCVD method, it is possible to improve the crystallinity of the PZT film (ferroelectric film 34) on the Ir atoms of the lower electrode 33. Therefore, composition control will become easier by using the MOCVD method. In forming the PZT film (ferroelectric film 34), liquid material is normally used as the source. However, it is also possible to form the PZT film by MOCVD using THF (tetrahydrofuran) as a solvent, and Pb(dpm)₂/THF, Ti(iPr)₂(dpm)₂/THF and Zr(iPr)₂(dpm)/THF as source materials, where film forming temperature is rendered 600° C. or over and oxygen is used as a reactive gas, for example.

At a time of forming the lower ferroelectric film 34C and the upper ferroelectric film 34D, within a predetermined range of thickness from the surface of the lower electrode 33, because of the presence of the nano-structures 75, the lower ferroelectric film 34C is formed as being composed of crystal particles which are smaller in particle size than those produced under normal film forming conditions, crystal particles which are oriented in a certain direction, or crystal particles with different compositions. Moreover, in a region above the region where the nano-structures 75 are formed, the upper ferroelectric film 34D with uniform composition and particle size that can be obtained under normal film forming conditions is formed. In the present embodiment, it is not necessary to have different crystal growth conditions between the film forming of the lower ferroelectric film 34C and the film forming of the upper ferroelectric film 34D. Furthermore, the upper ferroelectric film 34D can have its orientation influenced by the lower ferroelectric film 34C.

Next, a heat treatment is carried out at a temperature of 400 to 600° C. By this heat treatment, impurities such as carbon are removed from the ferroelectric film 34 as being the PZT film. Thus, a sectional structure as shown in FIG. 3H can be obtained. Then, the upper electrode 35 is formed on the ferroelectric film 34. The upper electrode is formed with a noble metal electrode film such Pt, Ir or the like, to a thickness of 100 nm or less. After that, as shown in FIG. 3I, a mask material 61 with a predetermined shape is formed on the upper electrode 35. The mask material 61 is formed with a hard mask which is composed of a resist or a Si oxide film. Then, by conducting an etching process using the mask material 61 as a mask, the ferroelectric capacitor 30 that contacts with the contact plug 26B is formed on the first interlayer insulation film 20, as shown in FIG. 3J. In FIG. 3J, the mask material 61 is being removed. In processing a capacitor for the FeRAM, in addition to processing the ferroelectric film 34 being PZT, SBT or the like, it is necessary to process a noble metal electrode which is capable of enduring film formation with a crystalline oxide. Therefore, there may be some cases in which conducting RIE processing at a high temperature of 200° C. or over using a halogen gas as an etching gas is preferable. Specifically, the ferroelectric capacitor 30 is processed using the mask material 61 which has been formed into a processing pattern of the ferroelectric capacitor. At this time, first, the upper electrode 35, the ferroelectric film 34 (PZT film) and the lower electrode 33 is etched in sequence while using the mask material 61 as a mask. Then, the capacitor barrier film 32 and the adhesive film 31 is etched in sequence. As an etching gas to be used in etching the capacitor barrier film 32 and the adhesive film 31, N₂, O₂, CO, Cl₂, CF₄, or the like can be used. As a material for the mask, it is possible to use a Si oxide film although it is not limited to the Si oxide film. It is also possible to use a Al oxide film or a conductive nitride film such as TiAlN or the like, or it is possible to use a material where such films are combined. The ferroelectric capacitor 30 having been formed through such processes is to have a structure where a hydrogen barrier layer such as Al₂O₃ is formed in around a connecting portion with the contact plug 26B. The mask material 61 is removed after the ferroelectric capacitor 30 has been shaped, for instance (cf. FIG. 3J).

Next, a heat treatment is carried out at a temperature of 400 to 600° C. in an atmosphere including oxygen. Thereby, damages caused on the ferroelectric film at the time of processing are recovered. After that, as shown in FIG. 1, the hydrogen barrier film 40 with a thickness of about 50 nm is formed in a way covering the entire ferroelectric capacitor 30 having been etch-processed. Furthermore, the second interlayer insulation film 41 composed of a silicon oxide film with a thickness of about 200 to 500 nm is formed on the hydrogen barrier film 40. Then, the via hole 42 for electrically connecting the upper electrode 35 of the ferroelectric capacitor 30 with an adjacent upper electrode of the ferroelectric capacitor 30, which is not shown, is formed, after which wiring is formed inside the formed via hole 42. Thereby, the semiconductor memory device shown in FIG. 1 will be obtained.

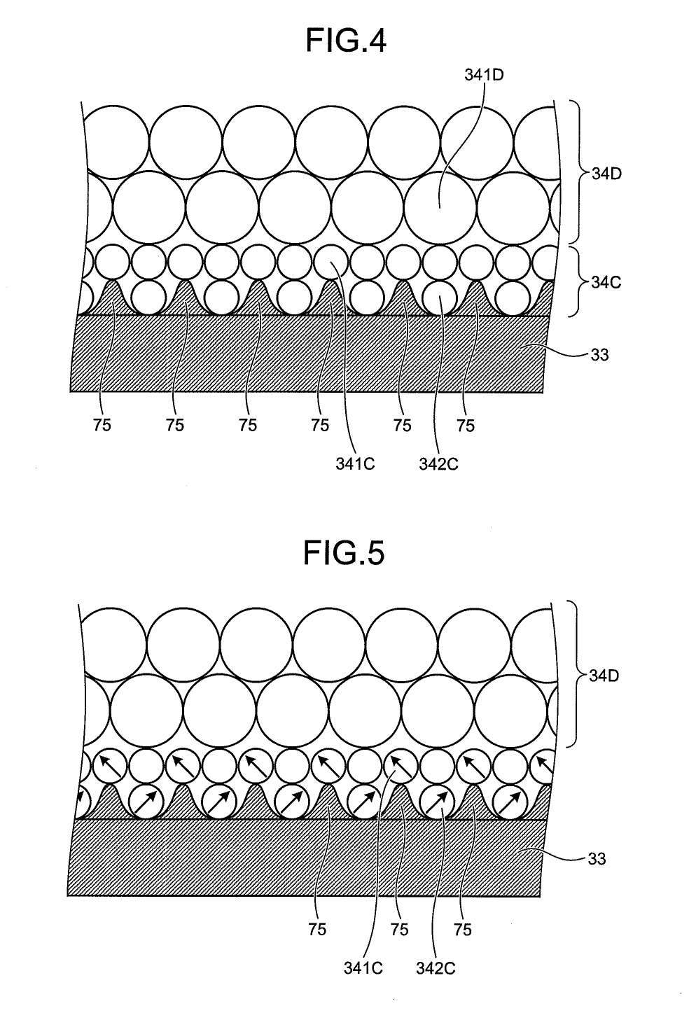

According to the first embodiment, due to having the ferroelectric film 34 formed on the lower electrode 33 that has the nano-structures 75, the lower ferroelectric film 34C as being composed of crystal particles with a particle size (e.g. several tens of nanometers or less) smaller than those produced under normal film forming conditions can be formed in the ferroelectric film 34 in the vicinity of the interface with the lower electrode 33. For example, as shown in FIG. 4, the lower ferroelectric film 34C includes crystal particles 341C that grow on the nano-structures 75 and crystal particles 342 C that grow on the lower electrode 33. Therefore, the crystal particles 341C and 342C that compose the lower ferroelectric film 34C have a particle size comparable with the size of the nano-structures 75 of which height and size in the in-plane direction are both 1 to 50 nm. This particle size is smaller than a particle size of crystal particles 341D that compose the upper ferroelectric film 34D which has been formed under the normal film forming conditions. As a result, in the semiconductor memory device shown in FIG. 1, stress that each crystal particle of the lower ferroelectric film 34C positioned in the vicinity of the interface between the ferroelectric film 34 and the lower electrode 33 receives will become smaller. Thereby, stress that can be put on the interface between the ferroelectric film and the electrode by an external structure can be reduced. Therefore, with the semiconductor memory device shown in FIG. 1, it is possible to reduce the stress put on the crystal particles composing the ferroelectric film 34, whereby the ferroelectric capacitor characteristic can be improved as compared to the conventional cases.

The crystal particles with the small particle size as formed in the ferroelectric film 34 in the vicinity of the interface with the lower electrode 33 can move easily and can easily cause polarization inversion along with a change of an external electric field. In the semiconductor memory device shown in FIG. 1, since the regions where these crystal particles with the small particle size are present function as domain cores, it is possible to make polarization inversion in the domain cores happen easily. As a result, the ferroelectric capacitor characteristic of the ferroelectric capacitor 30 according to the present embodiment can be improved as compared to the conventional cases. Furthermore, as mentioned above, in the semiconductor memory device shown in FIG. 1, the ferroelectric film 34 in the vicinity of the interface with the lower electrode 33 is formed with the crystal particles with the small particle size that can move easily and can easily cause polarization inversion when a direction of the electric field is changed. Therefore, even if a direction of an external electric field is changed, it is possible to absorb shape variation of the crystal particles in the ferroelectric film 34, which can be caused by inverse voltage effect, by the lower ferroelectric portion (i.e. lower ferroelectric film 34C) which is constituted from the crystal particles with the small particle size provided in the interface with the lower electrode 33. As a result, polarization inversion can be easily caused due to the easy occurrence of shape variation of the crystal particles, for which reason the ferroelectric capacitor characteristic can be improved as compared to the conventional cases. Moreover, by minimizing the size of the crystal particles, it is also possible to reduce possible variation in the ferroelectric capacitor characteristic with respect to each capacitor cell. In the semiconductor memory device shown in FIG. 1, since the ferroelectric film 34 in the vicinity of the interface with the lower electrode 33 is formed with the crystal particles with the small particle size, it is possible to reduce variation in the ferroelectric capacitor characteristic with respect to each capacitor cell, whereby homogenous ferroelectric capacitor characteristic can be achieved. In addition, in the semiconductor memory device shown in FIG. 1, since the interface between the ferroelectric film 34 and the lower electrode is densely formed by crystal particles with the small particle size, it is possible to prevent defects, such as film exfoliation, from occurring. Thereby, the ferroelectric characteristic of the ferroelectric film 34 can be maintained at high quality.

Moreover, according to the first embodiment, each of the nano-structures 75 is formed using LNO, SRO, or the like, which has the same perovskite structure as the ferroelectric film 34 and has good lattice matching, as its material. Since the ferroelectric film 34 is to be developed on such nano-structures 75 and on the lower electrode 33 being a metal film, it is possible to render the orientation of the crystal particles 342C having been grown on the surface of the lower electrode 33 different from the orientation of the crystal particles 341C having been grown on the surfaces of the nano-structures 75. Furthermore, according to the present embodiment, it is possible to achieve the ferroelectric film 34 as having a structure in which the crystal particles in the lower ferroelectric film 34C are orientated in a predetermined direction whereas the crystal particles in the upper ferroelectric film 34D are orientated in random directions. In addition, it is also possible to achieve the ferroelectric film 34 as having various orientations without being influenced by the lower electrode 33. In this way, even when the orientation of the crystal particles in the ferroelectric film 34 in the vicinity of the interface with the lower electrode 33 is changed, stress that each of the crystal particles in the ferroelectric film 34 positioned around the interface between the ferroelectric film 34 and the lower electrode 33 receives will be dispersed and therefore will be reduced. As a result, in the semiconductor memory device shown in FIG. 1, since stress put on the ferroelectric film 34 and/or the interface between the lower electrode 33 and the ferroelectric film 34 by the external structure can be reduced, it is possible to reduce the stress that can be put on the crystal particles composing the ferroelectric film 34. Thus, the ferroelectric capacitor characteristic of the ferroelectric capacitor 30 can be improved as compared to the conventional cases. Meanwhile, in forming the ferroelectric film 34 using the nano-structures 75, it is also possible to change the sizes of the crystal particles by stimulating ununiformity in crystal growth.

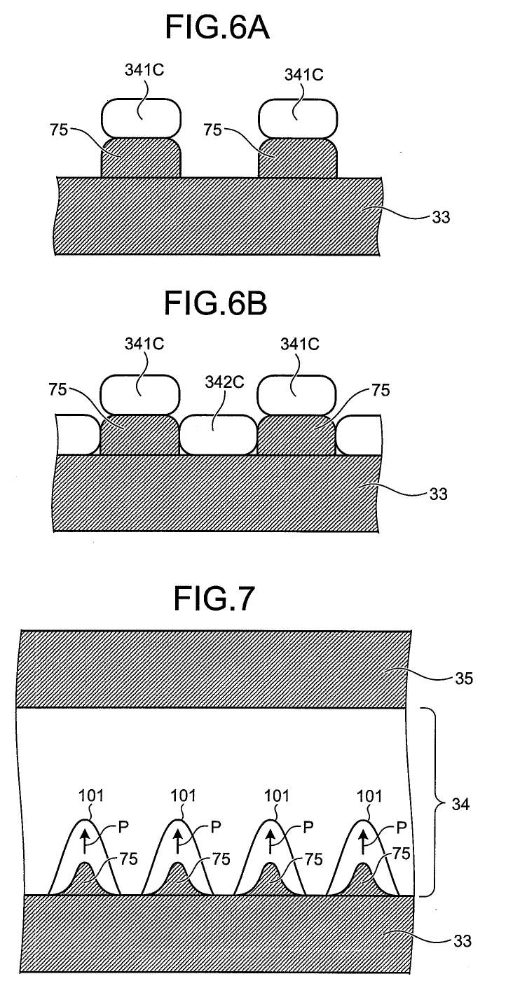

Moreover, according to the first embodiment, it is possible to change the composition between the crystal particles 341C that grow on the surfaces of the nano-structures 75 and the crystal particles 342C that grow on the surface of the lower electrode 33. This is because the adhesion behavior with respect to each of the elements; Pb, Ti and Zr, is different between the nano-structure 75 being formed as adopting LNO, SRO, or the like as its material and the lower electrode 33 being formed as adopting a noble metal such as Ir. Here, the PZT film which is Ti rich can easily be precipitated at low temperature. Therefore, as shown in FIG. 6A, each of the nano-structures 75 is formed using LNO, SRO, or the like, which has the same perovskite structure as the ferroelectric film 34 and has good lattice matching with the ferroelectric film 34, as its material, and the crystal particles 342C as being crystal particles of Ti-rich PZT are formed selectively on such nano-structures 75 using different deposition temperatures. Then, as shown in FIG. 6B, the crystal particles 342C as being crystal particles of PZT of normal composition is formed on the lower electrode 33. By forming the ferroelectric film 34 in this way, in the semiconductor memory device shown in FIG. 1, it is capable of locally forming a structure, which has a composition where polarization inversion can be easily caused, in a region of the ferroelectric film 34 around the interface with the lower electrode 33. As a result, in the semiconductor memory device shown in FIG. 1, such composition regions where polarization inversion can be easily caused will function as inversion domain cores when a direction of the external electric field is changed, whereby development of the inversion domains is stimulated. Therefore, the ferroelectric capacitor characteristic of the ferroelectric capacitor 30 can be improved as compared to the conventional cases. Furthermore, when the surface of the lower electrode 33 is shaped into a concave-convex surface due to the nano-structures 75 being formed, the electric field will concentrate at the convex parts. Therefore, in the semiconductor memory device shown in FIG. 1, the domain will grow from an upper part of the convex portion, i.e. a region 101 on the nano-structure 75, in a thickness direction as indicated by an arrow P in FIG. 7. Thereby, polarization inversion of the ferroelectric film 34 can be caused easily.

Meanwhile, after the crystal particles 341C being Tr-rich PZT are selectively formed on the nano-structures 75 as shown in FIG. 6A, it is also possible to have the crystal particles 342C being Zr-rich PZT selectively formed on the lower electrode 33, as shown in FIG. 6B, by switching the film forming conditions of the lower ferroelectric film 34C to film forming conditions for forming Zr-rich PZT. In this way, in the semiconductor memory device shown in FIG. 1, by controlling the compositions of the crystal particles to be formed on the nano-structures 75 and the crystal particles to be formed on the lower electrode 33, it is possible to make polarization inversion of the ferroelectric film 34 happen easily even more.

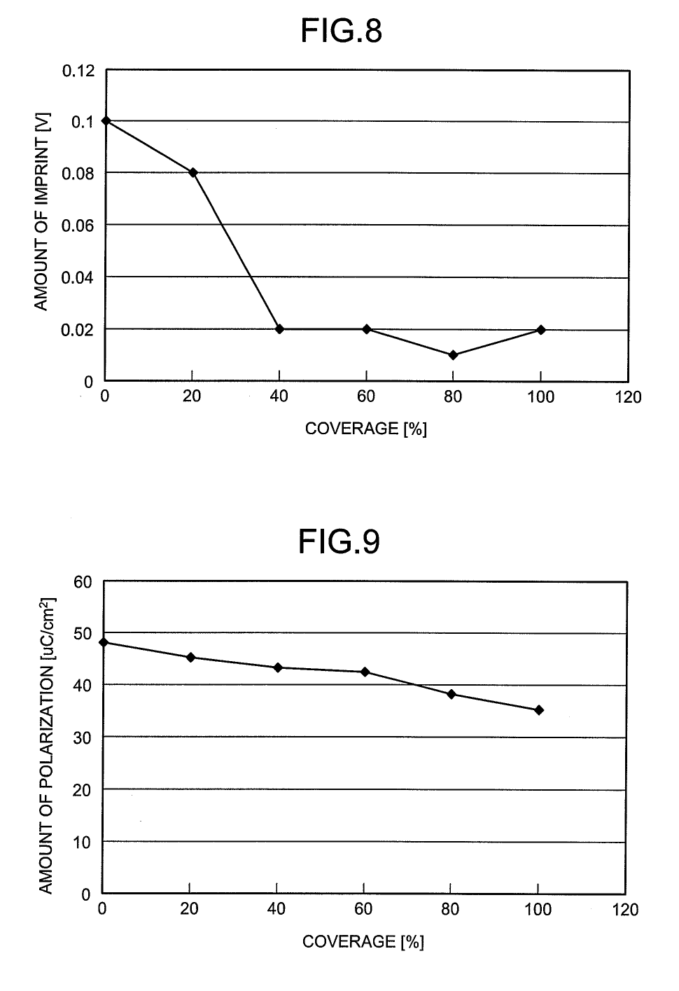

Moreover, in the semiconductor memory device of FIG. 1, by forming the nano-structures 75 in way that they cover 20% to 80% of the surface area of the lower electrode 33, it is possible to further improve the reliability of the semiconductor memory device. Semiconductor memory devices have actually been manufactured while changing the coverage of the nano-structures 75, which are formed with conductive oxides, with respect to the surface of the lower electrode 33 to 0%, 20%, 40%, 60%, 80% and 100%, respectively. With respect to each of the semiconductor memory devices with different coverage of the nano-structures 75, values for the amount of imprint and polarization have been measured. FIG. 8 is a diagram showing a relation between the coverage of the nano-structures 75 with respect to the surface of the lower electrode 33 and the amount of imprint as obtained by such measurement. FIG. 9 is a diagram showing a relation between the coverage of the nano-structures 75 with respect to the surface of the lower electrode 33 and the amount of polarization as obtained by the same measurement.

As shown in FIG. 8, when the surface of the lower electrode 33 was not covered with the nano-structures 75, i.e. when the coverage was 0%, the amount of imprint was 0.1 V, which is comparatively large. On the other hand, when the surface of the lower electrode 33 was covered with the nano-structures 75, the amount of imprint decreased. Particularly, with the cases where the coverages are 40%, 60% and 80%, the measurement results indicated decrease in the amount of imprint that went down to 0.01 to 0.02 V. In this way, by forming the nano-structures 75 in a way covering 20% to 80% of the surface of the lower electrode, it is possible to reduce the amount of imprint. Thereby, the reliability of the semiconductor memory device can be improved. Furthermore, as shown in FIG. 9, the amount of polarization was about 48 V in the case where the coverage was 0%, and scarcely changed in the case where the coverage of the nano-structures was rendered 20%. Even in the case where the coverage was increased up to 80%, decrease in the amount of polarization stayed to the extent as little as down to 39 V. Based on such experiment, in the case where the coverage is 20% to 80% for the surface of the lower electrode 33, it has been found that it is possible to reduce the amount of imprint to a considerable extent without losing the amount of polarization of the semiconductor memory device even if the nano-structures 75 using the conductive oxides are formed on the lower electrode 33.

Moreover, although the first embodiment has been described as referring to the case where LNO or SRO is used in forming the nano-structures 75, the nano-structures 75 are not limited to such form. The nano-structures can also be formed using IrOₓ, TiOₓ, YBa₂Cu₃O₇ (YBCO), LSCO, or the like. In such cases also, the lower ferroelectric film 34C can be formed in the ferroelectric film 34 around the interface with the lower electrode 33 as being composed of crystal particles which are smaller in particle size than those produced under normal film forming conditions, crystal particles which are oriented in a certain direction, or crystal particles with different compositions.

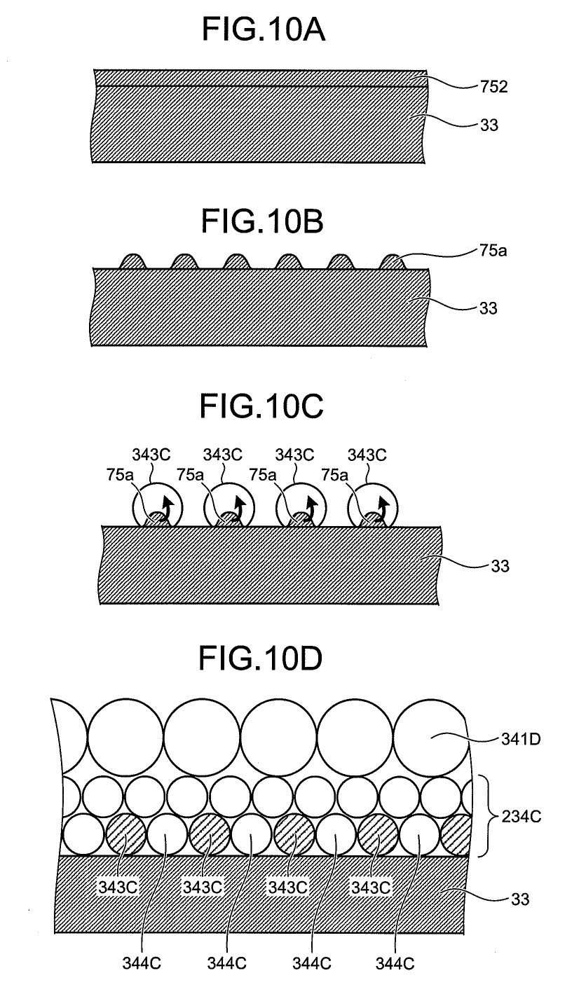

Moreover, the nano-structures 75 can also be formed using a metal material such as Ta, Nb, or the like. In such case, as shown in FIG. 10A, a nano-structure base film 752 composed of a material such as Ta or Nb as having a thickness of 10 Å or less is formed on the lower electrode 33 by a sputtering method or the like. Then, by letting the nano-structure base film 752 aggregate by a heat treatment, nano-structures 75a formed with Ta or Nb with a height and a size in an in-plane direction being 1 to 50 nm can be formed on the surface of the lower electrode 33, as shown in FIG. 10B. Then, with a process similar to the manufacturing process as described with reference to FIG. 3F, the lower ferroelectric film 34C is formed on the lower electrode 33 that has the nano-structures 75a formed with Ta or Nb. In this case also, as with the case of forming the nano-structures 75 using LRO or SRO as the material, the lower ferroelectric film 34C can be formed in the ferroelectric film 34 around the interface with the lower electrode 33 as being composed of crystal particles which are smaller in particle size than those produced under normal film forming conditions, crystal particles which are oriented in a certain direction, or crystal particles with different compositions.

Moreover, in the case of forming the nano-structures 75a using Ta or Nb as the material, crystal particles 343C of PZT is formed in a way taking in the nano-structures 75a, having been formed using Ta or Nb as the material, as cores, as indicated by arrows shown in FIG. 10C. Then, crystal particles 344C of PZT of normal composition are formed on the surface of the lower electrode 33. Therefore, in the case of forming the nano-structures 75a using Ta or Nb as the material, it is possible to have a lower ferroelectric film 234C, which includes the crystal particles 344C of PZT that comply with the film forming conductions and the crystal particles 343C of PZT that take in Ta or Nb as the cores, developed selectively in the ferroelectric film 34 in the vicinity of the interface with the lower electrode 33, as shown in FIG. 10D. Here, in the case where Ta or Nb has been taken into PZT as the core, the ferroelectric characteristic such as the amount of polarization can be controlled in a hardware-wise manner. That is, it is possible to prevent the ferroelectric characteristic from deteriorating using hardware-wise controllability. Therefore, in the case of forming the nano-structures 75a using Ta or Nb as the material, the crystal particles 343C of PZT that take in Ta or Nb as the cores can be formed selectively, whereby deterioration of the ferroelectric characteristic of the ferroelectric film 34 can be prevented using the above-mentioned hardware-wise controllability. As a result, a semiconductor memory device where deterioration of the ferroelectric characteristic can be further prevented can be manufactured.

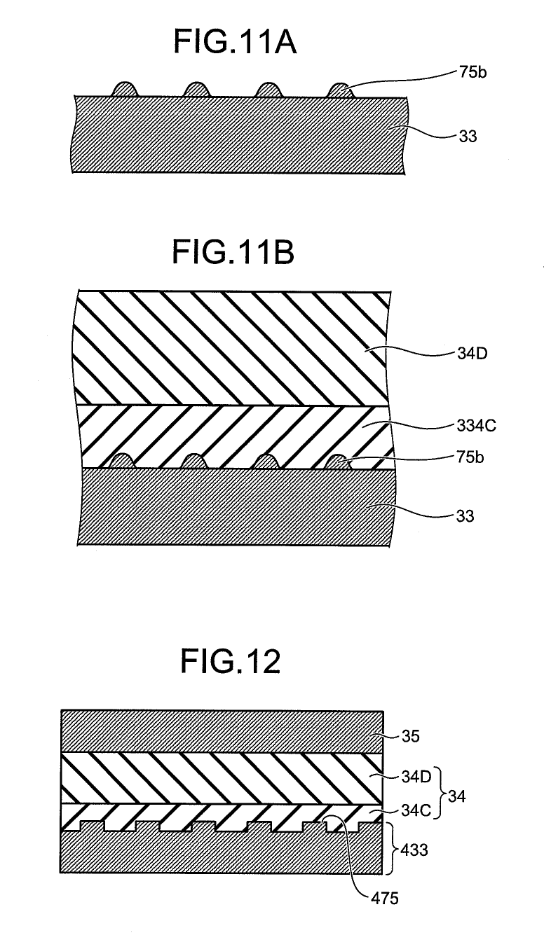

Moreover, it is also possible form the nano-structures using PZT being the material of the ferroelectric film 34. For example, as shown in FIG. 11A, by chancing the amount of material supply, a PZT film is formed on the lower electrode 33 in islands arrangement under film forming conditions that renders Ti-rich condition. Such Ti-rich PZT film having been formed into the islands arrangement will function as nano-structures 75b similarly to the above-described nano-structures 75. Then, by switching the amount of material supply to a normal condition, a lower ferroelectric film 334C is formed. Since this ferroelectric film 334C is formed on the lower electrode 33 having the nano-structures 75b, the ferroelectric film 334C is composed of crystal particles which have a small particle size, crystal particles which are oriented in a certain direction, or crystal particles with different compositions. As a result, with the case of manufacturing the ferroelectric capacitor 30 by the manufacturing processes shown in FIG. 11A and FIG. 11B, it is likewise possible to manufacture a semiconductor memory device with improved ferroelectric capacitor characteristic as compared to the conventional cases. In addition, in forming the lower ferroelectric film 334C, it is also possible to have PZT films with different orientations formed sequentially by changing a film forming temperature among the film forming conditions.

### Second Embodiment

Now a semiconductor memory device and a method of manufacturing thereof according to a second embodiment of the present invention will be described. The second embodiment will refer to a case in which a concave-convex shape, which functions similarly to the nano-structures in the first embodiment, is formed on the surface of the lower electrode by processing the surface of the lower electrode.

FIG. 12 is a partial sectional view schematically showing one example of a structure of the semiconductor memory device according to the second embodiment of the present invention. In FIG. 12, parts of the structure other than a lower electrode 433 of the ferroelectric capacitor 30, the ferroelectric film 34, and the upper electrode 35 are similar to those in the structure shown in FIG. 1, and such parts therefore are not shown for brevity.

In the semiconductor memory device according to the second embodiment, convex portions 475 are formed on the surface of the lower electrode 433. A height of each of theses convex portions 475 is 1 to 50 nm, or preferably 1 to 20 nm, and a size thereof in an in-plane direction is 1 to 50 nm, or preferably 1 to 30 nm. The ferroelectric film 34 composed of the lower ferroelectric film 34C and the upper ferroelectric film 34D is formed on the lower electrode 433 having such convex portions 475 on the surface. The lower ferroelectric film 34C has a finer structure than the upper ferroelectric film 34D. In the semiconductor memory device shown in FIG. 12, the convex portions 475 on the surface of the lower electrode 433 will exhibit a function similar to that of the nano-structures 75 in the first embodiment. Thereby, the lower ferroelectric film 34C is formed in the ferroelectric film 34 around the interface with the lower electrode 433 as being composed of crystal particles which are smaller in particle size than those produced under normal film forming conditions, crystal particles which are oriented in a certain direction, or crystal particles with different compositions.

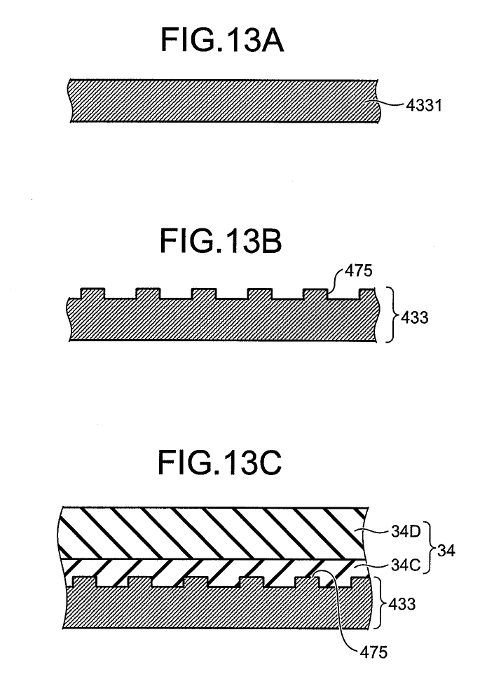

Now, a method of manufacturing the semiconductor memory device having such structure will be described. FIG. 13A to FIG. 13J are sectional views schematically showing one example of processes in the method of manufacturing the semiconductor memory device according to the second embodiment of the present invention. In the following, description of manufacturing processes which are the same as those in the first embodiment will be omitted for the sake of brevity. Here, as with the case of the first embodiment, the description will be about a case in which PZT is used as the ferroelectric film 34.

As described with reference to FIG. 3A to FIG. 3B with respect to the first embodiment, the first interlayer insulation film 20 is formed on the semiconductor substrate 1 where the MISFET 3 is being formed, and the contact plugs 26A and 26B which contact with the source/drain regions 10A and 10B of the MISFET 3, respectively, are formed in the first interlayer insulation film 20, after which the adhesive film 31 composed of TiAl or the like, and the capacitor barrier film 32 composed of TiAlN or the like is formed sequentially on the first interlayer insulation film 20. Then, a lower electrode base film 4331 composed of Ir, for instance, is formed on the capacitor barrier film 32. Thereby, a sectional structure shown in FIG. 13A can be obtained. The lower electrode base film 4331 is a conductive film to be processed into the lower electrode 433, and is formed with the same material as the lower electrode 433.

Next, as shown in FIG. 13B, the convex portions 475 are formed on the surface of the lower electrode base film 4331. These convex portions 475 can be formed by: a dry etching process such as RIE, CDE or the like, using a reactive gas; a heat treatment in a gas atmosphere of some kind of gas; a process by some kind of chemical; or a combination of such processes. Thereby, the shape of the upper surface of the lower electrode 433 with the convex portions 475 becomes a concave-convex shape. With respect to the Ir film formed by a sputtering method, in-plane orientations of the atoms are random. From this perspective, using differences of etching rates among different plane orientations in the Ir crystal, an RIE process is performed under conditions that make parts of a crystal face with a low etching rate in the Ir film remain as having convex shapes. Thereby, the parts of the crystal face with the low etching rate that expose on the surface can be shaped into convex portions 475. Optionally, it is also possible to form the convex portions 475 on the surface of the lower electrode 433 by carrying out a heat treatment on the Ir film, having been formed by sputtering, at a temperature of 700° C. or over, and then let Ir on the film surface recrystallize.

Next, in processes similar to the manufacturing processes shown in FIG. 3F and FIG. 3G, a MOCVD method is used to have the lower ferroelectric film 34C that composes the ferroelectric film 34 formed in-situ on the lower electrode 433 having the convex portions 475, after which the upper ferroelectric film 34D that composes the ferroelectric film 34 is formed (cf. FIG. 13C). Then, the processes as described with reference to FIG. 3H and beyond that with respect to the first embodiment are performed. Thereby, the semiconductor memory device according to the present embodiment can be manufactured.

As with the case of the first embodiment, in the second embodiment also, the lower ferroelectric film 34C can be formed in the ferroelectric film 34 around the interface with the lower electrode 433 as being composed of crystal particles which are smaller in particle size than those produced under normal film forming conditions, crystal particles which are oriented in a certain direction, or crystal particles with different compositions. Thereby, in the present embodiment, it is possible to reduce the stress on the electrode interface and cause polarization inversion easily. As a result, the ferroelectric capacitor characteristic can be improved.

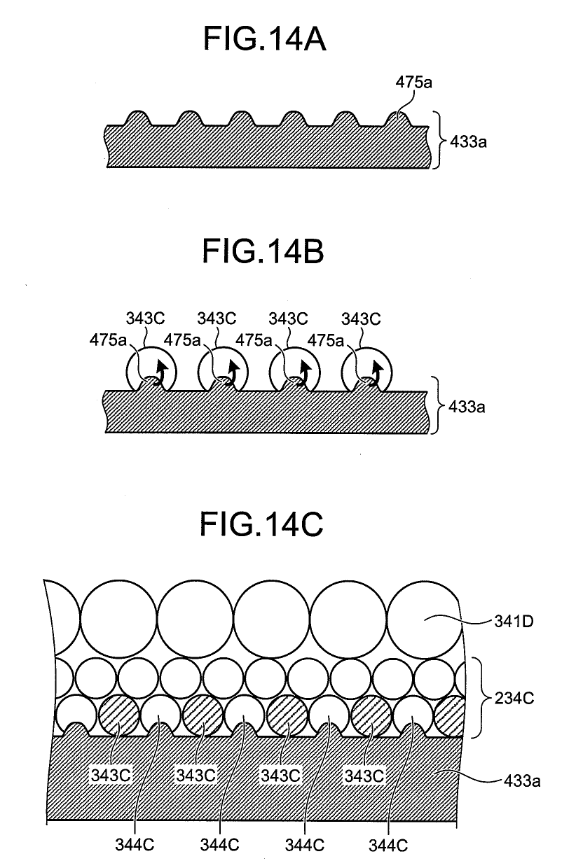

In the second embodiment, it is also possible to form the lower electrode 433 as having an alloy composition by doping Ta or Nb to the noble metal being the material of the lower electrode 33. That is, the lower electrode 33 can include Ta or Nb as dopant. In such case, Ta or Nb can be locally precipitated on the surface, as shown in FIG. 14A, by adjusting a target composition, or by performing a heat treatment after the film formation. As a result, convex portions 475a of Ta or Nb are formed on a surface of a lower electrode 433a. Then, with a process similar to the manufacturing process as described with reference to FIG. 3F, the lower ferroelectric film 34C is formed on the lower electrode 433a where convex portions of Ta or Nb are formed on the surface. In such case, crystal particles 343C of PZT are formed in a way taking in Ta or Nb of the convex portions 475a as cores, as indicated by arrows shown in FIG. 14B. Then, as shown in FIG. 14C, crystal particles 344C of PZT are formed on the surface of the lower electrode 433a on which the crystal particles 343C are formed. In the case of forming the convex portions 475a by precipitating Ta or Nb, it is possible to have a lower ferroelectric film 234C, which includes the crystal particles 344C of PZT that comply with the film forming conditions and the crystal particles 343C of PZT that take in Ta or Nb as the cores, developed selectively in the ferroelectric film 34 in the vicinity of the interface with the lower electrode 433a, as shown in FIG. 14C. Therefore, by controlling the ferroelectric characteristic of the lower ferroelectric film 234C, such as the amount of polarization, in a hardware-wise manner, a semiconductor memory device where deterioration of the ferroelectric characteristic can be further prevented can be manufactured.

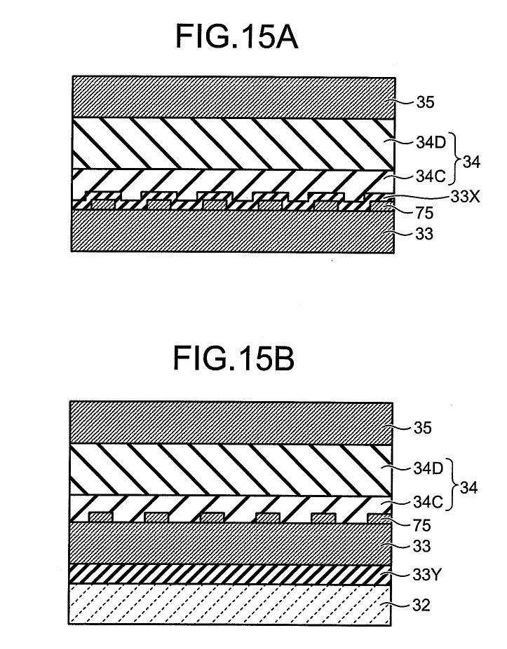

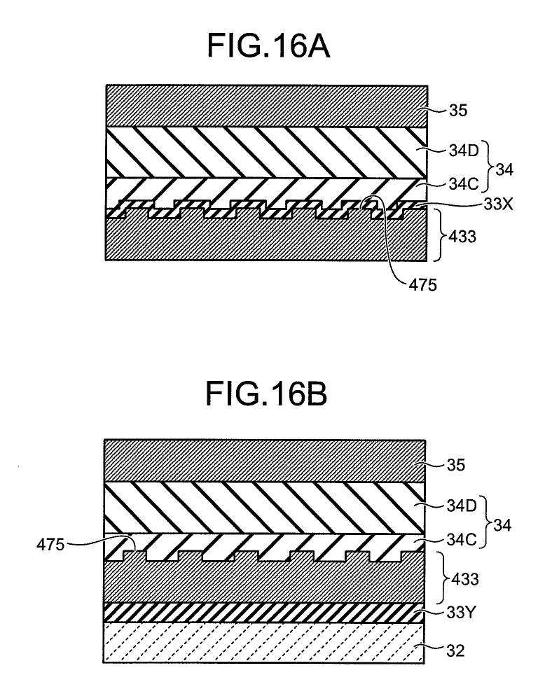

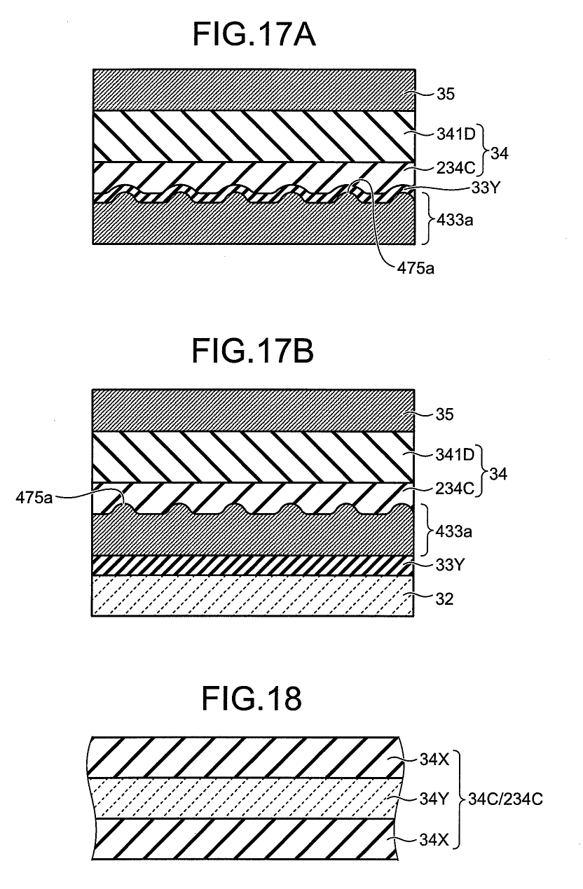

In the first embodiment described above, as shown in FIG. 15A or FIG. 15B, it is also possible to have a buffer layer 33X or 33Y formed with a IrOₓ film, a RuOₓ film, etc. arranged in between the lower electrode 33/433/433a and the lower ferroelectric film 34C/234C, or in between the lower electrode 33/433/433a and the capacitor barrier film 32. Accordingly, stress relaxation between the films can be enhanced, whereby characteristics such as the amount of polarization can be improved. Likewise, in the second embodiment described above, as shown in FIG. 16A or FIG. 17A, or as shown in FIG. 16B or FIG. 17B, it is also possible to have a buffer layer 33X or 33Y formed with a IrOₓ film, a RuOₓ film, etc. arranged in between the lower electrode 433/433a and the lower ferroelectric film 34C/234C, or in between the lower electrode 33/433/433a and the capacitor barrier film 32. FIGS. 15A and 15B are partial sectional views schematically showing a modified example of a structure of the ferroelectric capacitor in the semiconductor memory device according the first embodiment of the present invention. FIGS. 16A, 16B, 17A and 17B are partial sectional views schematically showing a modified example of a structure of the ferroelectric capacitor in the semiconductor memory device according to the second embodiment of the present invention.

It is also possible to form the lower ferroelectric film 34C/234C with a plurality of layers having different compositions. Thereby, it will be possible to have the domains inverted easily, whereby the ferroelectric capacitor characteristic can be improved. For example, as shown in FIG. 18, by forming one of the plurality of films 34X that compose the lower ferroelectric film 34C/234C with Zr-rich PZT film 34Y which exhibits a behavior in that domain inversion can be made easily, a region where this Zr-rich PZT film 34Y is formed will be made to function as an inversion domain core. Thereby, the ferroelectric capacitor characteristic can be improved. FIG. 18 is a partial sectional view schematically showing a modified example of the lower ferroelectric film 34C/234C according to the first or second embodiment of the present invention.

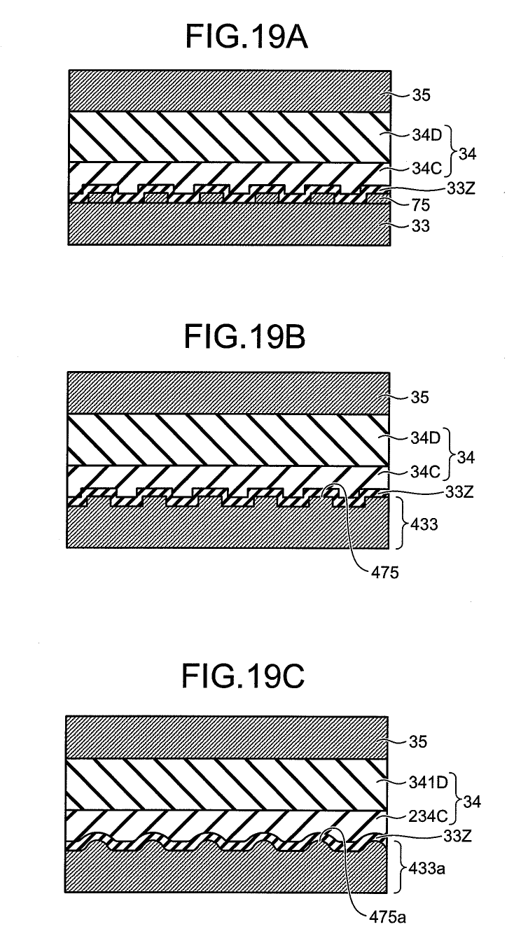

In a case of using Pt as material of the lower electrode 33/433/433a, as shown in FIGS. 19A to 19C, it is also possible to form a SRO film 33Z on the lower electrode 33/433/433a, i.e. between the lower electrode 33/433/433a and the lower ferroelectric film 34C/234C. Thereby, polarization inversion will repeatedly occur in the interface with the PZT film used as the ferroelectric film 34, and thus, fatigue degradation in that the amount of polarization will decrease can be prevented. FIG. 19A is a partial sectional view schematically showing a modified example of a structure of the ferroelectric capacitor in the semiconductor memory device according to the first embodiment of the present invention. FIG. 19B is a partial sectional view schematically showing a modified example of a structure of the ferroelectric capacitor in the semiconductor memory device according to the second embodiment of the present invention, and FIG. 19C is a partial sectional view schematically showing a modified example of a structure of the ferroelectric capacitor in the semiconductor memory device according to the second embodiment of the present invention. In a case of forming the PZT film by sputtering, in particular, interface defects will increase, for which reason it is preferable that the SRO film is formed on the lower electrode 33/433/433a. Here, by forming concave-convex portions on the surface of the SRO film by executing a heat treatment or an etching process on the SRO film, it is possible to have such concave-convex portions function similarly to the nano-structures 75. It is also possible to form the SRO film on the side of the upper electrode 35. In such structure, in view of the symmetrical ability of the structure of the ferroelectric capacitor 30, it is also possible to form the SRO film in between the lower electrode 33/433/433a and the ferroelectric film 34 regardless of the constituent material of the lower electrode 33/433/433a. Furthermore, in a case of forming the ferroelectric film 34 at a low temperature, the capacitor barrier 32 may be unnecessary, and thus can be omitted.

Moreover, it is also possible to form a defect suppressive region in the ferroelectric film in the vicinity of the interface with the lower electrode by replacing a part of the constituent elements of the ferroelectric film with a metal element in a substituted element film. For example, in the case where the ferroelectric film 34 is being composed of PZT, Pb²⁺ that dominates cite A of the perovskite structure can volatilize easily. Therefore, along with the volatilization of Pb²⁺, O²⁻ will also deflate. This is because oxygen ions in the perovskite structure such of PZT are in a most close-packed structure where the oxygen ions can move comparatively easily. When oxygen deflation happens, oxygen deficiency will occur in the crystal structure. Such oxygen deficiency will form space charge, defect dipole, etc., which may result in causing bad influence on polarization control. In this respect, oxygen deficiency can be made to occur less by making O²⁻ less deflatable by replacing a part of cite A with La³⁺ or Nb⁵⁺ which is less volatilizable from a solid. Furthermore, it is also possible to make O²⁻ less deflatable by replacing a part of cite B dominated by Zr⁴⁺ and Ti⁴⁺ with Mn. This is based on the aspect that O²⁻ will be held up inside the crystal by positive charges of Mn ions that dominate cite B, even under a state in which Pb²⁺ of cite A is being deflated. As a result, oxygen deficiency in the crystal structure can be made less occurrable. That is, in the case where the ferroelectric film 34 is being PZT, a defect suppressive region where an element such as La, Nb, Mn or the like is added will be provided in the lower ferroelectric film 34C/234C that composes the vicinity of the interface on the side of the lower electrode 33. Thereby, it is possible to manufacture a semiconductor memory device in which oxygen deficiency, lattice defect, etc. in the ferroelectric film in the vicinity of the interface with the lower electrode can be prevented. In such case, the interface portion will have the characteristic of both the doped PZT and the PZT in a bulk layer. Therefore, interface-induced stress and characteristic degradation due to crystal orientation and grain size can be made controllable. Furthermore, by forming such defect suppressive regions with different compositions into islands arrangement (concave-convex shape), it is possible to let the island portions function as the nano-structures.

In order to have the lattice constant of PZT match with the lower electrode 33/433/433a, a part of cite A in PZT of the lower ferroelectric film 34C/234C may be replaced with at least one kind of element to be selected from among a group of metals including Ba, Sr, Ca, La, etc. and/or a part of cite B may be replaced with at least one kind of element to be selected from among a group of metals including Co, Ni, W, Fe, Hf, Sn, Zn, Ta, Mg, Mn, Nb, etc.

Moreover, dopant can be introduced into the lower electrode 33/433/433a in order to have the lattice constant of the lower electrode 33/433/433a approximate the lattice constant of the ferroelectric film 34. Thereby, oxygen deficiency, lattice defect, etc. can be made less occurrable, as a result of which defect density in the ferroelectric film 34 in the vicinity of the interface with the lower electrode 33 can be reduced. In such case, by having the lattice constant of the lower electrode 33/433/433a approximate the lattice constant of the ferroelectric film 34, the ferroelectric film 34 will develop under the influence of the crystal structure of the lower electrode 33/433/433a as being the base. Therefore, even when the ferroelectric film 34 to be formed will be a polycrystalline film, it will be possible to reduce crystal defect density in the ferroelectric film 34 in the vicinity of the interface with the lower electrode 33. As a material for the lower electrode 33/433/433a, Ir can be used. It is also possible to dope a metal such as Ru, Ti, Pd, Pt, or the like into the lower electrode 33/433/433a made with Ir in order to have the lattice constant of the Ir approximate the lattice constant of the ferroelectric film being a PZT film or the like. Furthermore, by rendering such metal a solid solution in the Ir, it will be possible to prevent interface stress.

Moreover, it is also possible to form the PZT crystal film from a PZT film formed into an amorphous state. In such case, by forming a TiOₓ film partially in the amorphous PZT film, for example, it is possible to have the TiOₓ and the PZT react at the time of crystallization heat treatment. Therefore, it will be possible to form a PZT film which is partially Ti-rich. Such Ti-rich PZT film will have a characteristic in that the amount of polarization is large and switching is difficult. Accordingly, it is possible to partially change the electric characteristic within the PZT film.

As described above, according to the embodiments of the present invention, it is possible to provide a semiconductor memory device, which has improved ferroelectric capacitor characteristic as compared to the conventional cases, and a method of manufacturing such semiconductor memory device.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a field effect transistor comprising a source and a drain region;
an interlayer insulation film around the field effect transistor;
a ferroelectric capacitor comprising a lower electrode, a ferroelectric film and an upper electrode, the lower electrode with a concave-convex surface, a height and a size in an in-place direction of each convex portion in the concave-convex surface being 1 nanometer to 50 nanometer, the ferroelectric film comprising a lower ferroelectric film with a predetermined height from the lower electrode and an upper ferroelectric film on the lower ferroelectric film of the same material as the lower ferroelectric film, and the lower ferroelectric film comprising a portion comprising at least one of composition, crystallizing orientation and size of a crystalline particle being different from a crystalline particle in the upper ferroelectric film; and
a plug configured to electrically connect between the source and the drain region and the ferroelectric capacitor.

2. The semiconductor memory device of claim 1, further comprising:
a buffer layer lying either between the lower electrode and the lower ferroelectric film or under the lower electrode, the buffer layer absorbing stress between layers.

3. The semiconductor memory device of claim 1, wherein
the lower ferroelectric film comprises a plurality of ferroelectric layers, and
a composition of at least one of the plurality of ferroelectric layers is different from a composition of another ferroelectric layers.

4. The semiconductor memory device of claim 1, further comprising:
a SrRuO₃ film lying between the lower electrode and the lower ferroelectric film, wherein
the lower electrode comprises Platinum (Pt) as a material.

5. The semiconductor memory device of claim 1, further comprising:
a nano-structure at the surface of the lower electrode, a height and a size in an in-place direction of the nano-structure being 1 nanometer to 50 nanometer, wherein
the concave-convex surface comprises the nano-structure.

6. The semiconductor memory device of claim 5, wherein
the nano-structure comprises at least one of LaNiO₃ (LNO), SrRuO₃ (SRO), iridium oxide (IrOₓ), titanium oxide (TiOₓ), YBa₂Cu₃O₇ (YBCO), CoO(La, Sr)₃ (LSCO), Tantalum (Ta), Niobium (Nb) and Pb(Zrₓ,Ti₁₋ₓ)O₃ (PZT) as a construction material.

7. The semiconductor memory device of claim 5, wherein
the nano-structure comprises a conductive oxide and covers 20% to 80% of the surface of the lower electrode.

8. The semiconductor memory device of claim 1, wherein
the lower electrode comprises a concave-convex pattern at the surface of the lower electrode, a height and a size in an in-place direction of each convex portion in the concave-convex pattern being 1 nanometer to 50 nanometer.

9. The semiconductor memory device of claim 8, wherein
the concave-convex pattern covers 20% to 80% of the surface of the lower electrode.

10. The semiconductor memory device of claim 8, wherein
the lower electrode comprises Ta or Nb as dopant.

11. A method of manufacturing a semiconductor memory device comprising:
forming a field effect transistor comprising a source and a drain region;
forming an interlayer insulation film surrounding the field effect transistor;
forming a contact hole in the interlayer insulation film, the contact hole exposing the source and the drain region;
forming a plug inside the contact hole, the plug configured to electrically connect to the source and the drain region;
forming a lower electrode on the interlayer insulation film, the lower electrode configured to electrically connect to the plug and comprising a concave-convex surface, a height and a size in an in-place direction of each convex portion in the concave-convex surface being 1 nanometer to 50 nanometer;
forming a ferroelectric film by crystallization on the concave-convex surface of the lower electrode; and
forming an upper electrode on the ferroelectric film.

12. The method of manufacturing a semiconductor memory device of claim 11, comprising
forming the ferroelectric film by crystallization under substantially high temperature.

13. The method of manufacturing a semiconductor memory device of claim 11, comprising
forming the ferroelectric film with a metal-organic chemical vapor deposition (MOCVD) method.

14. The method of manufacturing a semiconductor memory device of claim 11, wherein
a size in an in-place direction of each convex portion in the concave-convex surface is 1 nanometer to 30 nanometer.

15. The method of manufacturing a semiconductor memory device of claim 11, wherein
the lower electrode comprising the concave-convex surface is formed by forming an electrode layer with a flat surface on the interlayer insulation film, and forming a nano-structure at the flat surface of the electrode layer, a height and a size in an in-place direction of the nano-structure being 1 nanometer to 50 nanometer, and
the concave-convex surface comprises the nano-structure.

16. The method of manufacturing a semiconductor memory device of claim 15, wherein
the nano-structure is formed by forming a base layer on the electrode layer using a material of the nano-structure, and thermal treating the base layer in such a manner that the base film is processed into the nano-structure.

17. The method of manufacturing a semiconductor memory device of claim 15, wherein
the nano-structure comprises a conductive oxide and covers 20% to 80% of the surface of the lower electrode.

18. The method of manufacturing a semiconductor memory device of claim 11, wherein
the lower electrode is formed in such a manner that a concave-convex pattern is formed at the surface of the lower electrode, a height and a size in an in-place direction of each convex portion in the concave-convex pattern being 1 nanometer to 50 nanometer, and
the concave-convex surface is formed by the concave-convex pattern formed at the surface of the lower electrode.

19. The method of manufacturing a semiconductor memory device of claim 18, wherein
the concave-convex pattern is formed by forming a conductive film on the interlayer insulation film using a material of the lower electrode, and processing a surface of the conductive film using at least one of a dry etching, a heat treatment and a chemical solution treatment.

20. The method of manufacturing a semiconductor memory device of claim 18, wherein
the concave-convex pattern covers 20% to 80% of the surface of the lower electrode.
